(19) United States
(12) Patent Application Publication
(10) Pub. No.: US 2017/0105315 A1
(43) Pub. Date: Apr. 13, 2017

(54) HEAT CONDUCTIVE PLASTIC RADIATOR AND COMMUNICAITON DEVICE

(71) Applicant: Sercomm Corporation, Taipei (TW)

(72) Inventor: Yuan-Heng Huang, Taipei (TW)

(73) Assignee: Sercomm Corporation, Taipei (TW)

(21) Appl. No.: 15/284,544

(22) Filed: Oct. 4, 2016

(30) Foreign Application Priority Data
Oct. 12, 2015 (CN) 201520788149.0

(51) Int. Cl. H05K 7/20; H05K 1/02; F28F 21/06

(52) U.S. Cl. CPC H05K 7/20409; F28F 21/06; H05K 1/0203; H05K 2201/066; H05K 2201/10098

(57) ABSTRACT

A heat conductive plastic radiator and a communication device are provided. The communication device includes the heat conductive plastic radiator, a communication chip and an antenna. The heat of the communication chip is dissipated by the heat conductive plastic radiator. Along any direction, the heat conductive plastic radiator has a plurality of cross-sections perpendicular to the direction, and the plurality of cross-sections have different shapes. Therefore, one of the advantages of the heat conductive plastic radiator is that it less severely interferes with the antenna while efficiently dissipating heat.

### CROSS-REFERENCE TO RELATED APPLICATION

This application claims the priority benefit of Chinese application serial no. 201520788149.0, filed on Oct. 12, 2015. The entirety of the above-mentioned patent application is hereby incorporated by reference herein and made a part of this specification.

### BACKGROUND OF THE INVENTION

Field of the Invention

The invention relates to a radiator and a communication device, and particularly relates to a heat conductive plastic radiator and a communication device.

Description of Related Art

Based on an effective heat dissipation design, electronic devices may have advantages of high reliability, stability and high service life, and may overcome a development restriction on high-speed electronic chips. In the past, a heat radiator of aluminium extrusion molding is generally adopted to exchange heat with a heat source of an electronic device, though it may use excessive materials and have high processing cost. Moreover, the heat radiator of aluminium extrusion molding has a plurality of cross-sections perpendicular to a direction of aluminium extraction, but all the plurality of cross-sections have the same shapes. If additional appearance variation is required, an additional cutting process, etc. has to be performed, which results in more cost. Moreover, when a metal radiator is applied to the communication device, the metal radiator may negatively affect the efficiency of an antenna in the communication device. The metal radiator may probably enlarge an electromagnetic interference effect to influence the operation of the communication device.

### SUMMARY OF THE INVENTION

The invention is directed to a heat conductive plastic radiator and a communication device, which may reduce costs and reduce interference with the operation of the communication device.

The invention provides a heat conductive plastic radiator. Along any direction, the heat conductive plastic radiator has multiple cross-sections perpendicular to the direction, and the multiple cross-sections have different shapes. One of the advantages of the heat conductive plastic radiator is that it less severely interferes with the antenna while efficiently dissipating heat

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a partial three-dimensional view of a heat conductive plastic radiator applied to a communication device according to an embodiment of the invention, and FIG. 1B is a top view of the heat conductive plastic radiator applied to the communication device.

FIG. 2A and FIG. 2B are respectively two cross-sections in different shapes of the heat conductive plastic radiator of FIG. 1B perpendicular to a same direction D12 and viewing along section lines I-I and II-II.

FIG. 3 is a cross-section view of the heat conductive plastic radiator of FIG. 1A combined with a communication chip.

FIG. 4 is a top view of a heat conductive plastic radiator according to another embodiment of the invention.

### DESCRIPTION OF EMBODIMENTS

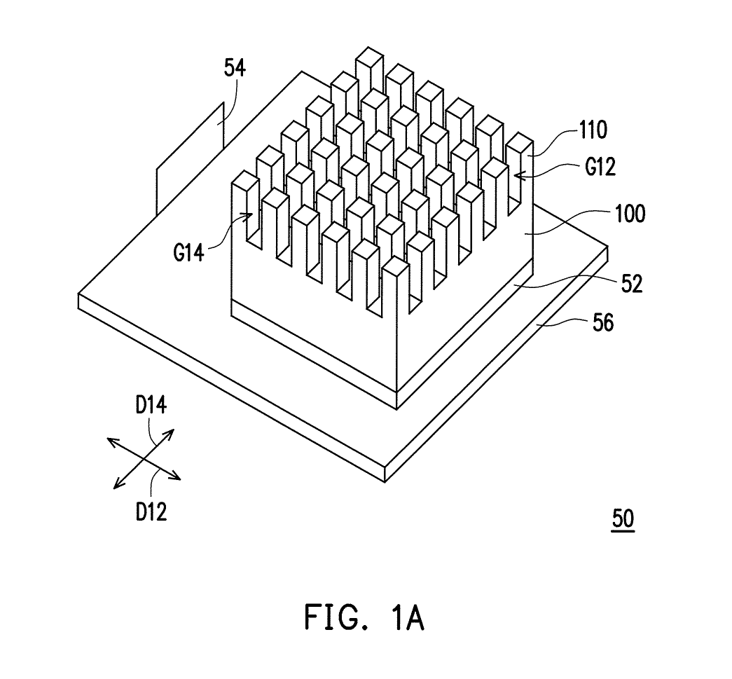

FIG. 1A is a partial three-dimensional view of a heat conductive plastic radiator applied to a communication device according to an embodiment of the invention, and FIG. 1B is a top view of the heat conductive plastic radiator applied to the communication device. Referring to FIGS. 1A and 1B, besides the components that are not shown, the communication device 50 of the present embodiment includes heat conductive plastic radiator 100, a communication chip 52 and an antenna 54. The communication chip 52 and the antenna 54 are, for example, electrically connected through a circuit board 56.

Heat of the communication chip 52 is dissipated by the heat conductive plastic radiator 100. Namely, the communication chip 52 and the heat conductive plastic radiator 100 have a good heat conduction path there between, and the heat generated during the operation of the communication chip 52 can be conducted to the heat conductive plastic radiator 100 to escape outward. The heat conductive plastic radiator 100 and the communication chip 52 may further clamp a soft thermal pad there between. The heat conductive plastic radiator 100 of the present embodiment is pervious to electromagnetic wave, and has little or none interference on efficiency of the antenna 54. Therefore, the antenna 54 is ensured to have a good clearance zone to achieve a larger operating frequency bandwidth and an operating frequency thereof is maintained. Moreover, the heat conductive plastic radiator 100 is less likely to enlarge an electromagnetic interference effect to influence the operation of the communication device 50 or peripheral devices.

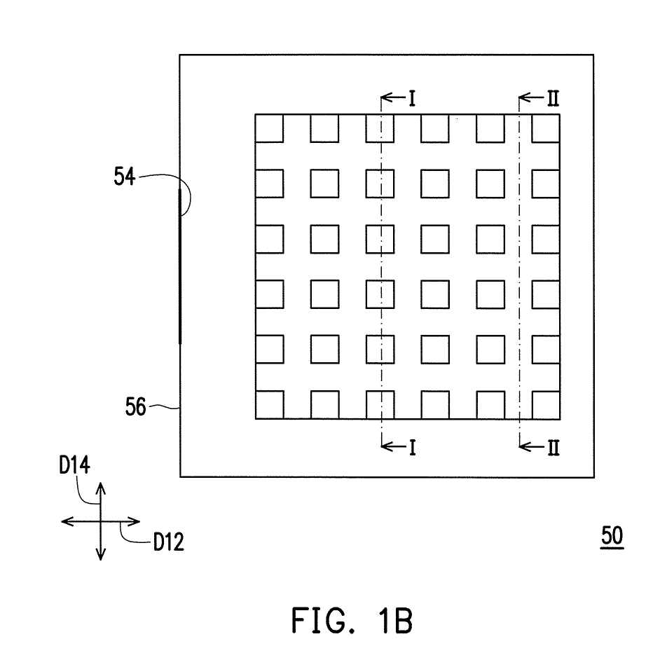

Moreover, along any direction, the heat conductive plastic radiator 100 of the present embodiment has a plurality of cross-sections perpendicular to the direction, and the plurality of cross-sections have different shapes. FIG. 2A and FIG. 2B are respectively two cross-sections in different shapes of the heat conductive plastic radiator 100 of FIG. 1B, wherein the two cross-sections are perpendicular to a same direction D12. Referring to FIG. 1B, the heat conductive plastic radiator 100 has a cross-section S12 as shown in FIG. 2A and a cross-section S14 as shown in FIG. 2B perpendicular to the direction D12, and shapes of the cross-section S12 and the cross-section S14 are different to each other. Similarly, the heat conductive plastic radiator 100 of the present embodiment has two cross-sections perpendicular to a direction D14, and the two cross-sections have different shapes. Besides the direction D12 and the direction D14, the heat conductive plastic radiator 100 of the present embodiment has a plurality of cross-sections perpendicular to any direction and in different shapes. Namely, the heat conductive plastic radiator 100 of the present embodiment has great flexibility in appearance design, and a process such as injection molding can be adopted to complete the required overall appearance at one time, so as to decrease processing steps to lower a manufacturing cost. In view of the conventional heat radiator of aluminium extrusion molding, the cross-sections perpendicular to the aluminium extrusion are all the same. In an embodiment, the heat conductive plastic radiator 100 is a single piece. Namely, the heat conductive plastic radiator 100 of the present embodiment is inseparable, and the required functional structures are all formed on the heat conductive plastic radiator 100 integrally, and it is unnecessary to additionally combine other functional structures.

Referring to FIG. 1A, the heat conductive plastic radiator 100 of the present embodiment has a plurality of cooling fins 110, and the cooling fins 110 are separated by a plurality of first grooves G12 and a plurality of second grooves G14 there between. The first grooves G12 are arranged in parallel to the direction D12, where the direction D12 is referred to as a first direction. The second grooves G14 are arranged in parallel to the direction D14, where the direction D14 is referred to as a second direction. The first direction D12 is different to the second direction D14. By configuring the grooves of different directions, heat dissipation efficiency of the heat conductive plastic radiator 100 is improved. Moreover, the process such as the injection molding can be adopted to complete the heat conductive plastic radiator 100 at one time. In contrast, the conventional heat radiator of aluminium extrusion molding, an additional milling process is required in order to form the grooves of different directions.

A thermal conductivity of the heat conductive plastic radiator 100 of the present embodiment is greater than or equal to 15 W/m·° K, which provides good heat dissipation efficiency to the communication chip 52. Regarding an experiment performed by using a communication chip with power consumption of 6.4 W in collaboration with a heat conductive plastic radiator with the thermal conductivity of 15 W/m·° K, in an environment temperature of 26.6° C., the temperature of the communication chip is decreased from 103° C. to 83° C. The heat conductive plastic radiator 100 of the present embodiment may be formed by plastic doped with materials capable of improving thermal conductivity such as graphite, graphene, Al₂O₃, SiC, etc.

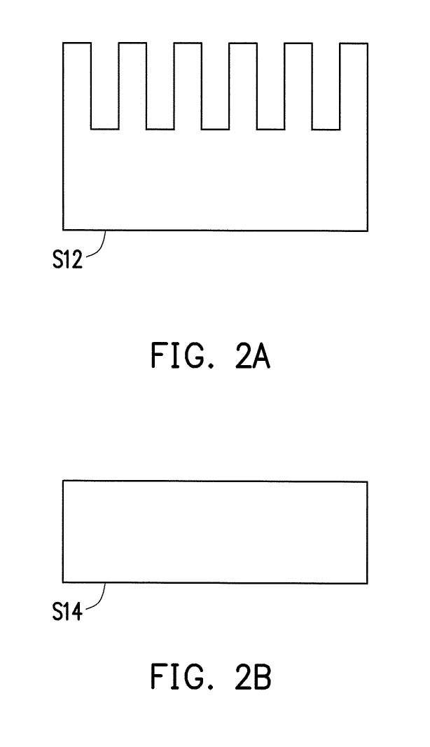

FIG. 3 is a cross-section view of the heat conductive plastic radiator of FIG. 1A combined with the communication chip. Referring to FIG. 3, the heat conductive plastic radiator 100 of the present embodiment has a bottom surface 120, and the bottom surface 120 has a recessed region 122, and the recessed region 122 contains a part of the communication chip 52. In other words, the bottom surface 120 includes a plurality of different planes, for example, a plane P12 located in the recessed region 122 and a plane P14 located outside the recessed region 122. In this way, not only the recessed region 122 of the bottom surface 120 of the heat conductive plastic radiator 100 may indeed receive heat of a chip 52A of the communication chip 52 through heat conduction, the other portion of the bottom surface 120 of the heat conductive plastic radiator 100 may also receive heat of a carrier board 52B beside the chip 52A through heat conduction, such that the overall heat dissipation efficiency of the heat conductive plastic radiator 100 is improved. Therefore, a heat dissipation requirement of the communication chip 52 is satisfied to improve computing efficiency, such that the communication chip 52 may have advantages of high reliability, stability and high service life and may overcome a development restriction on high-speed electronic chip. Moreover, a soft thermal pad 58 (which is only shown in FIG. 3) or other soft thermal material can be placed on the bottom surface 120 of the heat conductive plastic radiator 100 to reduce the air existed between the heat conductive plastic radiator 100 and the communication chip 52 that probably causes heat resistance. Even more, even if a passive component such as a capacitor is disposed on the carrier board 52B beside the chip 52A to make the carrier board 52B uneven, the deformable soft thermal pad 58 can still be perfectly attached to the carrier board 52B to ensure good thermal conduction between the heat conductive plastic radiator 100 and the communication chip 52.

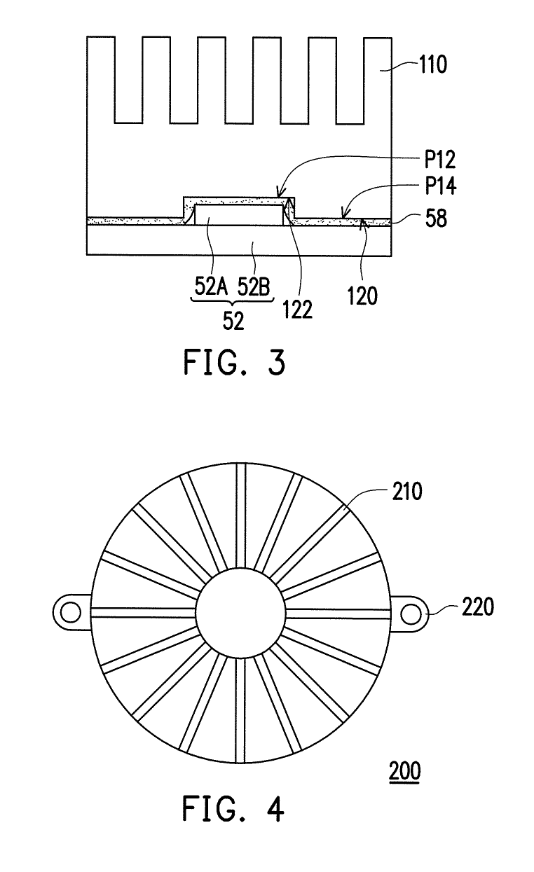

Other selective design of the invention is described below, though the invention is not limited thereto. FIG. 4 is a top view of a heat conductive plastic radiator according to another embodiment of the invention. Referring to FIG. 4, the heat conductive plastic radiator 200 of the present embodiment is similar to the heat conductive plastic radiator 100 of FIG. 1A, and a difference there between is that the cooling fins 210 are arranged in radial arrangement. The heat conductive plastic radiator 200 of the present embodiment may replace the heat conductive plastic radiator 100 of FIG. 1A/FIG. 3 for being applied in the communication device. Moreover, the heat conductive plastic radiator 200 of the present embodiment can be formed integrally with fixing ears 220, and is unnecessary to take other processes to configure the fixing ears 220. The design of the fixing ears can also be applied to the heat conductive plastic radiator 100 of FIG. 1A/FIG. 3 without taking additional processes.

In summary, in the heat conductive plastic radiator and the communication device, the heat conductive plastic radiator may not only improve heat dissipation efficiency to improve reliability of the communication device, but may also ensure the efficiency of the antenna and mitigate the electromagnetic interference to facilitate the communication device passing related testing. Moreover, the heat conductive plastic radiator can be manufactured in the injection molding manner, such that the material cost and manufacturing cost are all relatively low, and a flexibility in appearance thereof is relatively large without requiring additional processes.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A heat conductive plastic radiator, adapted to dissipate heat of a communication chip, wherein along any direction, the heat conductive plastic radiator has a plurality of cross-sections perpendicular to the direction, the plurality of cross-sections have different shapes, and the heat conductive plastic radiator is a single piece.

2. The heat conductive plastic radiator as claimed in claim 1, wherein the heat conductive plastic radiator has a plurality of cooling fins, and the cooling fins are arranged in radial arrangement.

3. The heat conductive plastic radiator as claimed in claim 1, wherein the heat conductive plastic radiator has a plurality of cooling fins, the cooling fins are separated by a plurality of first grooves and a plurality of second grooves there between, the first grooves are arranged in parallel to a first direction, the second grooves are arranged in parallel to a second direction, and the first direction is different to the second direction.

4. The heat conductive plastic radiator as claimed in claim 1, wherein a thermal conductivity of the heat conductive plastic radiator is greater than 15 W/m·° K.

5. A communication device, comprising a heat conductive plastic radiator, a communication chip, a circuit board and an antenna, wherein heat of the communication chip is dissipated by the heat conductive plastic radiator, the communication chip is electrically connected to the antenna through the circuit board, and along any direction, the heat conductive plastic radiator has a plurality of cross-sections perpendicular to the direction, the plurality of cross-sections have different shapes, and the heat conductive plastic radiator is a single piece.

6. The communication device as claimed in claim 5, wherein the heat conductive plastic radiator has a plurality of cooling fins, and the cooling fins are arranged in radial arrangement.

7. The communication device as claimed in claim 5, wherein the heat conductive plastic radiator has a plurality of cooling fins, the cooling fins are separated by a plurality of first grooves and a plurality of second grooves there between, the first grooves are arranged in parallel to a first direction, the second grooves are arranged in parallel to a second direction, and the first direction is different to the second direction.

8. The communication device as claimed in claim 5, wherein a thermal conductivity of the heat conductive plastic radiator is greater than 15 W/m·° K
